(19) United States
(12) Patent Application Publication
(10) Pub. No.: US 2003/0210582 A1
(43) Pub. Date: Nov. 13, 2003

(54) Semiconductor memory device having a side wall insulation film

(75) Inventor: Hideyuki Kinoshita, Mie-ken (JP)

Correspondence Address: OBLON, SPIVAK, MCCLELLAND, MAIER & NEUSTADT, P.C., 1940 DUKE STREET, ALEXANDRIA, VA, 22314, US

(73) Assignee: Kabushiki Kaisha Toshiba, Tokyo (JP)

(21) Appl. No.: 10/383,754

(22) Filed: Mar. 10, 2003

(30) Foreign Application Priority Data
Mar. 26, 2002 (JP) 2002-086678

(51) Int. Cl. G11C 7/00

(52) U.S. Cl. 365/200

(57) ABSTRACT

A semiconductor memory device having a side wall insulation film, comprises a first memory cell located on an active area of a semiconductor substrate, the first memory cell having a first gate electrode, a first source electrode and a first drain electrode; a second memory cell located on the semiconductor substrate, the second memory cell being apart from the first memory cell in a first distance and having a second gate electrode, a second source electrode and a second drain electrode; a silicon nitride layer formed above the first and second memory cells to cover the first and the second memory cells, a proportion of a thickness of the silicon nitride layer formed on a side surface of one of the first and second gate electrodes to the first distance between the first and the second memory cells being more than 0% and 15% or less.

### CROSS-REFERENCE TO RELATED APPLICATION

This application is based upon and claims the benefit of priority from the prior Japanese Patent Application No. 2002-086678, filed Mar. 26, 2002, the entire contents of which are incorporated herein by reference.

### BACKGROUND OF THE INVENTION

1. Field of the Invention

This present invention relates to a semiconductor memory device having a side wall insulation film, for example, a memory cell structure of an NAND flash type memory.

2. Description of the Related Art

Hereinafter, we will take an example of a memory cell structure of an NAND type flash memory device and explain about an interference operation between memory cells adjacent to each other, which could have been appeared by a down size of the NAND type flash memory device.

In a flash memory device, there are a NOR type and a NAND type flash memory devices typically. The NAND type flash memory device has an advantage of a high integration relative to the NOR type flash memory device. However, in the NAND type flash memory device, a distance between memory cells adjacent to each other is short and diffusion layers of a plurality of the memory devices are connected each other in series. Thereby, the NAND type flash memory has a structure in which the interference operation between the memory cells adjacent to each other tends to appear.

FIGS. 15(a), (b) and (c) show an example of a conventional NAND type flash memory device. FIG. 15(a) shows an equivalent circuit diagram of a memory cell portion. FIG. 15(b) shows a schematic plan view of the memory cell portion. FIG. 15(c) shows a schematic cross-sectional view of the memory cell portion. In FIGS. 15(a), (b) and (c), reference numbers 2 through 9 indicate control gates (CG), reference numbers 1 and 10 indicate select gates.

FIGS. 16(a) and (b) show a schematic cross-sectional view of the conventional NAND type flash memory device. FIG. 16(a) indicates a memory cell of an erase situation. (+) in FIG. 16(a) indicates a situation where electrons are pulled out of a floating gate, and on the other hand, (−) in FIG. 16(b) indicates a situation where electrons are injected into the floating gate as a matter of convenient.

FIGS. 17(a) and (b) show a detail cross-sectional view of the conventional NAND type flash memory device. FIG. 17(b) shows cross-sectional views perpendicular to the cross-sectional view of FIG. 17(a). As shown in FIGS. 17(a) and (b), a plurality of the memory cells are located on an element area of a semiconductor substrate 111 in the conventional NAND type flash memory device. Each of the memory cells has a silicon oxide 112 which is used as a first gate insulation film, a polycrystalline silicon layer 113 which is used as a floating gate (FG), an oxide nitride (ONO) layer 114 which is used as a second gate insulation film, and a polycrystalline silicon layer 115 which is used as control gate (CG). A silicon nitride layer 121 is formed so as to cover the plurality of the memory cells. Each of the plurality of the memory cells is covered with the silicon nitride layer 121.

We will explain about an appeared question by an increase of a capacity between memory cells adjacent to each other by down sizing of the memory cells. We will explain about the question by using FIGS. 18(a), (b), and (c) in which three memory cells are arranged as one example. As shown in FIG. 18(a), in the NAND type flash memory device, all of data stored in the memory cells are always erased before an execution of a program operation or reprogram operation. Namely, all of electrons injected into the floating gates of the memory cells are always pulled out of the floating gates of the memory cells. At a program operation, electrons are injected into the floating gates of the memory cells to be programmed if necessary. We assume that “0” data (higher threshold voltage of a memory cell) is stored in memory cells A and B in FIG. 18(a), and “1” data (lower threshold voltage of a memory cell) is stored in a memory cell C in FIG. 18(a). It is noted that “0” indicates a situation where data is programmed, and “1” indicates a situation where data is erased. And also, It is assumed that an order of a programming to the memory cell is A, B, and C in order. FIG. 18(b) shows a situation where data is programmed to the memory cell A, and the memory cells B and C remain erased. Similarly, FIG. 18(c) shows a situation where data are programmed to the memory cell B, and the memory cell C remain erased.

We will explain about a threshold voltage of the memory cell after data is programmed thereto by using a FIG. 18(c) and FIG. 19.

In the NAND type flash memory device, a programming operation is performed so that the threshold voltage of any of the memory cells to which data is programmed is constant value. However, when data is programmed to the memory cell B after programming to the memory cell A, a threshold voltage of the memory cell A changes due to a presence of a parasitic capacitor D shown in FIG. 18(c). Hereinafter, an alteration of the threshold voltage which is caused by this phenomenon is called as “an interference operation”. And a threshold voltage of the memory cell C does not change because a program operation is not performed for the memory cell C. On the other hand, a program operation is performed for the memory cell B with the parasitic capacitor D. Actually, the memory cells are arranged in two dimension. Therefore, the interference operation could occur due to a presence of parasitic capacitors between memory cells adjacent to each other in a same word line (a perpendicular direction to FIG. 18), and between a memory cell which is arranged in a NAND string and connected to a word line and a memory cell which is arranged in an adjacent NAND string and connected to an adjacent word line (a diagonal direction). Moreover, strength of the interference operation depends on a content of the data stored in the memory cell. And the more the number of the stored memory cell adjacent to a memory cell to be programmed are, the greater the interference operation influences to the memory cell to be programmed. Thereby, the strength of the interference operation is not always constant. Therefore, in a LSI, unevenness of the threshold voltage which is caused by unevenness of process accuracy and an applied voltage can take place. In addition, unevenness of the threshold voltage can be greater than we have expected.

We could have ignored the problem of interference operation between memory cells adjacent to each other before. However, as the memory cells are down-sized, we will not be able to ignore the problem. Thereby, following problems have appeared.

The threshold voltage of the memory cell can be changed toward a higher voltage than we predetermined. Thereby, a difference between voltage to make the non-selected memory cell turn on at a read operation and the threshold voltage of the memory cell could be small.

Also, we can give a magnitude of the alteration of the threshold voltage caused by the interference operation into design values in advance. However, it could make the design values (parameters) complex and an optimization of the design values difficult. Thereby, it results in low development efficiency.

Recently, in a multi-threshold level technique that allows one memory cell to store a plurality of data, a voltage used at a program operation is higher, and the interference operation is greater than those of a conventional two threshold level technique. In addition, the multi-threshold level technique needs more accurate control of a threshold distribution relative to the conventional two threshold level technique. Thereby, a difference between a threshold voltage and a voltage used at a read operation or a program operation tends to be small.

### SUMMARY OF INVENTION

A first aspect of the present invention is providing a semiconductor memory device having a side wall insulation film, comprising: a first memory cell located on an active area of a semiconductor substrate, the first memory cell having a first gate electrode, a first source electrode and a first drain electrode; a second memory cell located on the semiconductor substrate, the second memory cell being apart from the first memory cell in a first distance and having a second gate electrode, a second source electrode and a second drain electrode; a silicon nitride layer formed above the first and second memory cells to cover the first and the second memory cells, a proportion of a thickness of the silicon nitride layer formed on a side surface of one of the first and second gate electrodes to the first distance between the first and the second memory cells being more than 0% and 15% or less.

A second aspect of the present invention is providing 17. A semiconductor memory device having a side wall insulation film, comprising: a first memory cell located on an active area of a semiconductor substrate, the first memory cell having a first gate electrode, a first source electrode and a first drain electrode; a second memory cell located on the semiconductor substrate, the second memory cell being apart from the first memory cell in a first distance and having a second gate electrode, a second source electrode and a second drain electrode; first silicon nitride layers each of which formed above side surfaces of the first and second gate electrodes respectively; and a second silicon nitride layer formed above the first silicon nitride layer to cover the first and the second memory cells, a proportion of a total thickness of the first and the second silicon nitride layers formed on a side surface of one of the first and second gate electrodes to the first distance between the first and the second memory cells being more than 0% and 15% or less.

### BRIEF DESCRIPTION OF THE DRAWINGS

FIG. 1(a) shows a cross sectional view of a non-volatile semiconductor memory device of a first embodiment in a present invention. FIG. 1(b) shows a cross sectional view perpendicular to a non-volatile semiconductor memory device shown in FIG. 1(a).

FIG. 2 shows a manufacturing step of a non-volatile semiconductor memory device associated with the first embodiment of the present invention.

FIG. 3 shows a manufacturing step of a non-volatile semiconductor memory device associated with the first embodiment of the present invention followed by FIG. 2.

FIG. 4 shows a manufacturing step of a non-volatile semiconductor memory device associated with the first embodiment of the present invention followed by FIG. 3.

FIG. 5 shows a manufacturing step of a non-volatile semiconductor memory device associated with the first embodiment of the present invention followed by FIG. 4.

FIG. 6 shows a manufacturing step of a non-volatile semiconductor memory device associated with the first embodiment of the present invention followed by FIG. 5.

FIG. 7 shows a manufacturing step of a non-volatile semiconductor memory device associated with the first embodiment of the present invention followed by FIG. 6.

FIG. 8 shows a manufacturing step of a non-volatile semiconductor memory device associated with the first embodiment of the present invention followed by FIG. 7.

FIG. 9 shows a manufacturing step of a non-volatile semiconductor memory device associated with the first embodiment of the present invention followed by FIG. 8.

FIG. 10 shows a manufacturing step of a non-volatile semiconductor memory device associated with the first embodiment of the present invention followed by FIG. 9.

FIG. 11 shows a manufacturing step of a non-volatile semiconductor memory device associated with the first embodiment of the present invention followed by FIG. 10.

FIG. 12 shows a manufacturing step of a non-volatile semiconductor memory device associated with the first embodiment of the present invention followed by FIG. 11.

FIG. 13 shows a diagram that depicts a relationship between a width of a silicon nitride/a distance among gate electrodes and a fluctuation magnitude of a threshold voltage caused by an interference operation.

FIG. 14 shows a cross sectional view of a non-volatile semiconductor memory device of a second embodiment in the present invention.

FIGS. 15(a), (b), and (c) show exemplary diagrams of a conventional NAND type flash memory device. FIG. 15(a) shows an equivalent circuit of a memory cell portion. FIG. 15(b) shows a schematic plan view of the memory cell portion. FIG. 15(c) shows a schematic cross sectional view of the memory cell portion.

FIGS. 16(a) and (b) show schematic cross sectional views of a conventional NAND type flash memory device.

FIGS. 17(a) and (b) show schematic cross sectional views of a conventional NAND type flash memory device.

FIGS. 18(a), (b), and (c) show schematic cross sectional views of a conventional NAND type flash memory device.

FIG. 19 shows a diagram to explain a threshold voltage of a memory cell to which data is programmed by using a conventional technique.

FIG. 20 shows a diagram of a memory card in which a semiconductor memory device is arranged.

FIG. 21 shows a diagram of a memory card in which a semiconductor memory device and a controller are arranged.

FIG. 22 shows a diagram of a card holder to which a memory card is inserted.

FIG. 23 shows a diagram of a connecting apparatus, a board, and a connecting wire.

FIG. 24 shows a diagram of a PC, a connecting apparatus, and a connecting wire.

FIG. 25 shows a diagram of an IC chip including a semiconductor memory device, and an IC card on which the IC card is allocated.

FIG. 26 shows a schematic diagram of an IC card and an IC chip.

### DETAILED DESCRIPTION OF THE INVENTION

Hereinafter, we will explain about an embodiment of the present invention with reference to accompanying drawings. Common parts will be indicated by common reference symbol over all of the accompanying drawings.

A first embodiment of the present invention takes an example of an NAND type flash memory cell structure. This embodiment relates to a width of a silicon nitride that is used in a structure of the NAND type flash memory cell.

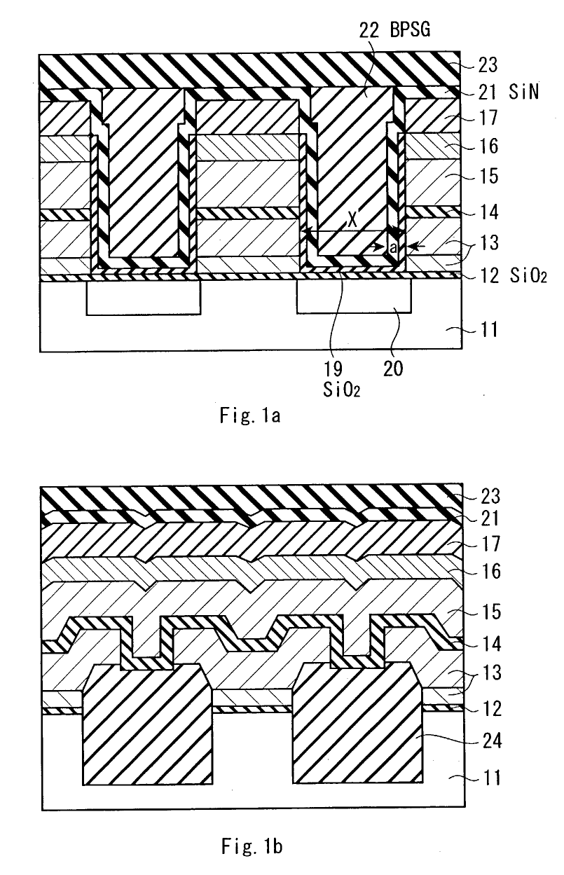

FIGS. 1(a) and (b) show cross sectional views of a non-volatile semiconductor memory device of the first embodiment in the present invention. As shown in FIGS. 1(a) and (b), in a non-volatile semiconductor memory device of the first embodiment, a plurality of memory cells are located on an active area of a semiconductor silicon substrate 11. Each of the memory cells includes a silicon oxide layer 12 that is used as a first gate insulation film, poly crystalline silicon layers 13 that are used as a floating gate (FG), an ONO layer that is used as a second gate insulation film, and a poly crystalline silicon layer 15 that is used as a control gate (CG). A silicon nitride layer 21 covers the plurality of the memory cells. Namely, each of the memory cells is covered with the silicon nitride layer 21. As shown by an inequality (1) as below, a width a of the silicon nitride layer 21 is 15% or less of a space width between gate electrodes adjacent to each other.

0%<(a/X) multiplied by 100<15% (1)

Sign “a” in the inequality (1) indicates a thickness of the silicon nitride layer. Sign “x” in the inequality (1) indicates a space width between gate electrode adjacent to each other.

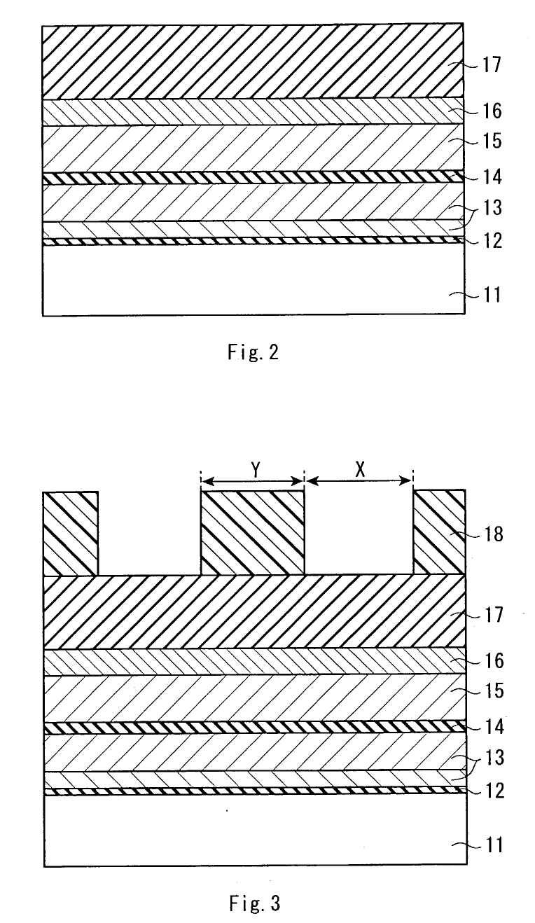

FIG. 2 to FIG. 12 show cross sectional views of manufacturing steps of the non-volatile semiconductor memory device of the first embodiment in the present invention. FIG. 2 to FIG. 12 show schematic cross sectional views from a step of forming control gates to a step of forming pre-metal dielectric. We will take an example of the NAND type flash memory device and explain about a method of manufacturing memory cells formed in the NAND type flash memory device.

As shown in FIG. 2, a silicon oxide layer 12 is formed on a semiconductor silicon substrate 11. A poly crystalline silicon layer 13 that is used as a floating gate, is formed on the silicon oxide layer 12. The poly crystalline silicon layers 13 can be comprised of a single layer. Alternatively, it can be comprised of two layers as shown in FIG. 2. Sequentially, an ONO layer 14 is formed on the poly crystalline silicon layers 13, and then, a poly crystalline silicon layer 15 that is used as a control gate, is formed on the ONO layer 14. A tungsten silicide layer 16 is formed on the poly crystalline silicon layer 15, and then, a silicon oxide layer 17 that is used as a mask for forming a control gate is formed on the tungsten silicide layer 16.

As shown in FIG. 3, a photo resist layer 18 with width of, for example, 500 nm is coated on the silicon oxide layer 17. By using lithography technique, the photo resist layer 18 is processed, thereby forming a pattern for forming control gates. A line width Y of a control gate pattern and a space width X are, for example, about 160 nm respectively.

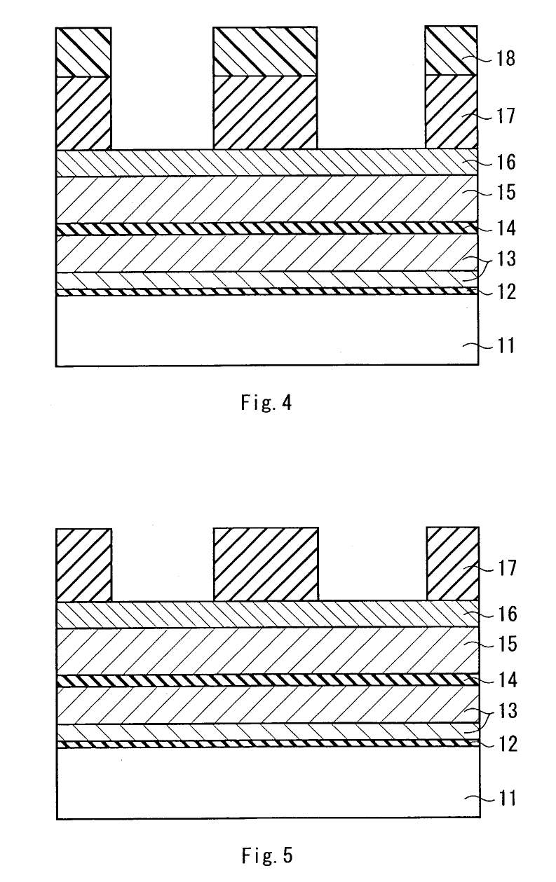

As shown in FIG. 4, by using a RIE (Reactive Ion Etching) method and using the photo resist layer 18 as a mask, the silicon oxide layer 17 is etched. After that, as shown in FIG. 5, by using an aching method, the photo resist layer 18 is removed.

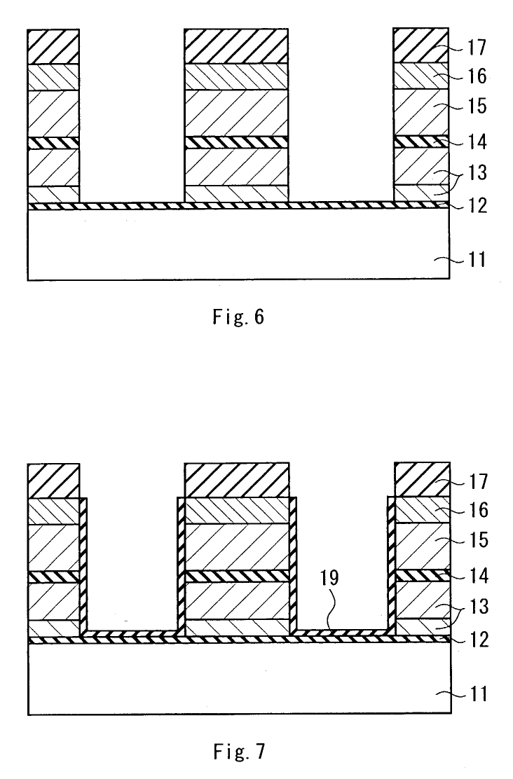

As shown in FIG. 6, by using a RIE method and using the silicon oxide layer 17 as a mask, the tungsten silicide layer 16, the poly crystalline silicon layer 15, the ONO layer 14, and the poly crystalline silicon layers 13 are etched. Thereby, predetermined gate pattern is formed.

As shown in FIG. 7, by using a RTP (Rapid Thermal Processing) technique, a silicon oxide layer 19 with a width of, for example, 10 nm on surfaces of the tungsten silicide layer 16, the poly crystalline silicon layer 15, the ONO layer 14, the poly crystalline silicon layers 13, and the silicon oxide layer 12. The silicon oxide layer 19 allows damages after forming gate electrodes to be recovered.

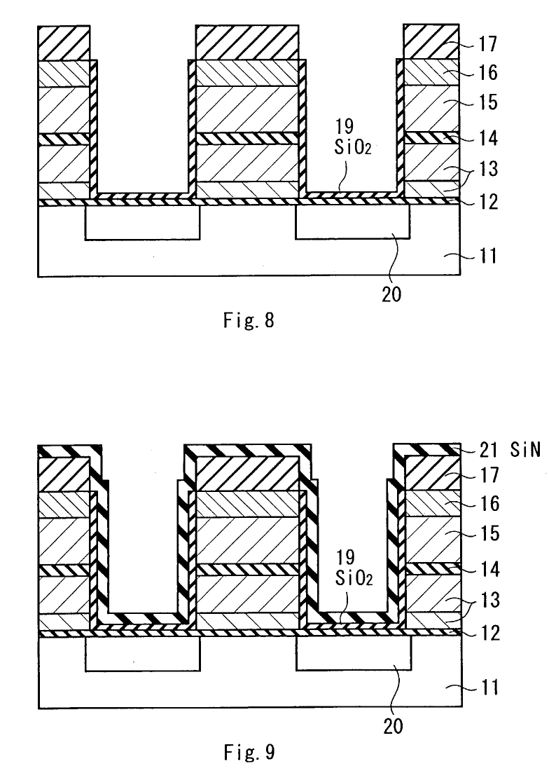

As shown in FIG. 8, by using an ion implantation technique and using P (Phosphorus) as impurities, phosphorus is injected to a surface of the semiconductor silicon layer 11. After that, a thermal process is performed with about 900 centigrade, thereby activating the injected impurities. Thereby, N type diffusion layers 20 are formed on the surfaces of the semiconductor silicon substrate 11.

As shown in FIG. 9, a silicon nitride layer 21 with a width of, for example, 20 nm is deposited on the silicon oxide layer 17 and 19 by using LPCVD (Low Pressure Chemical Vapor Deposition) technique. In a result, memory cells are covered with the silicon nitride layer 21. Even if anneal with an oxygen atmosphere is performed afterward, the silicon nitride layer 21 can prevent an oxidizer from reaching the semiconductor silicon substrate 11, and the tungsten silicide layer 16 from being oxidized excessively.

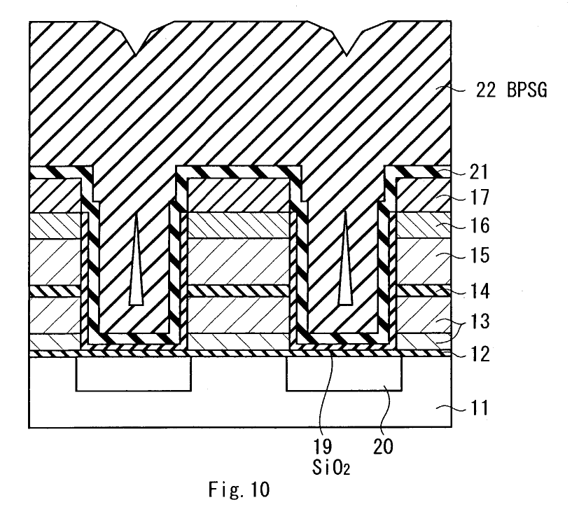

As shown in FIG. 10, a BPSG (Boron Phosphorus Silicate Glass) layer 22 with a width of, for example, 600 nm is deposited on the silicon nitride layer 21 by using a constant pressure CVD technique. After that, as shown in FIG. 11, a thermal process at about 800 centigrade is performed. Thereby, the BPSG layer 22 is reflowed.

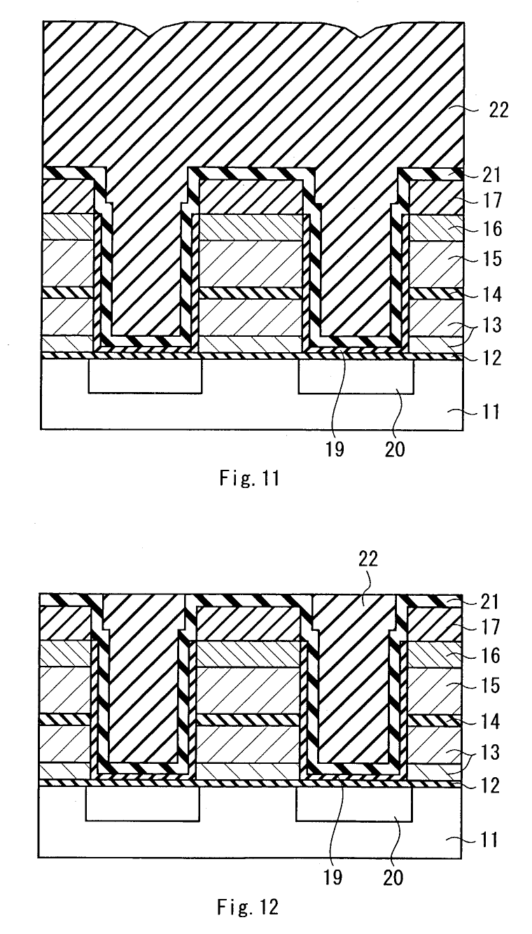

As shown in FIG. 12, a top surface of the BPSG layer 22 is flattened by using a CMP (Chemical Mechanical Polish) technique. At this time, the silicon nitride layer 21 is used as a stopper. In a result, this makes progress in a controllability of height of the BPSG layer 22.

As shown in FIGS. 1(a) and (b), a BPSG layer 23 with a width of about 50 nm is deposited on the silicon nitride layer 21 and the BPSG layer 22 in order to lower a capacitor between bit lines adjacent to each other.

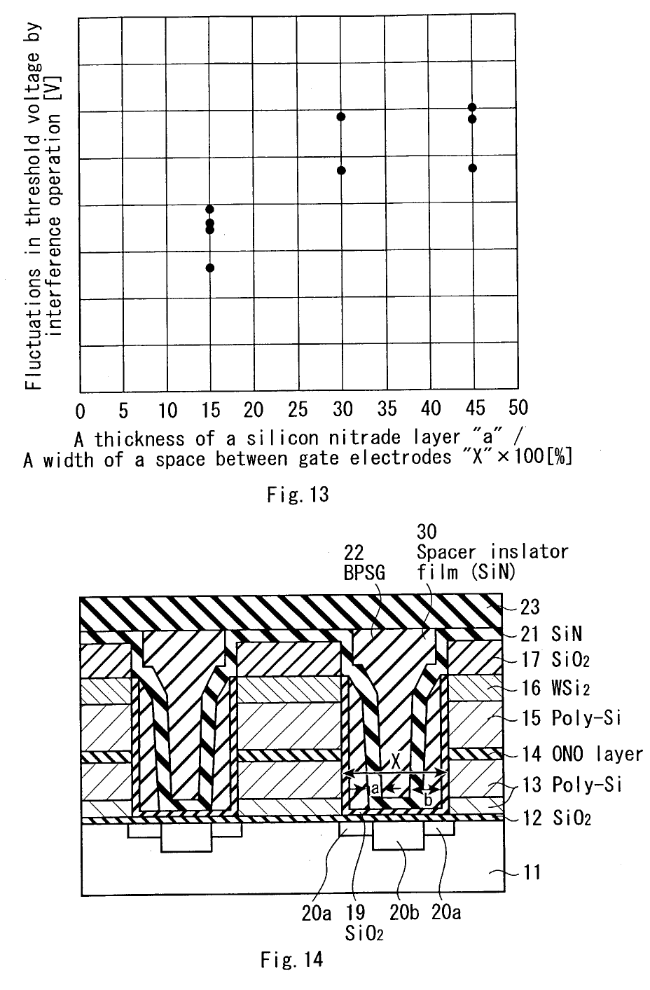

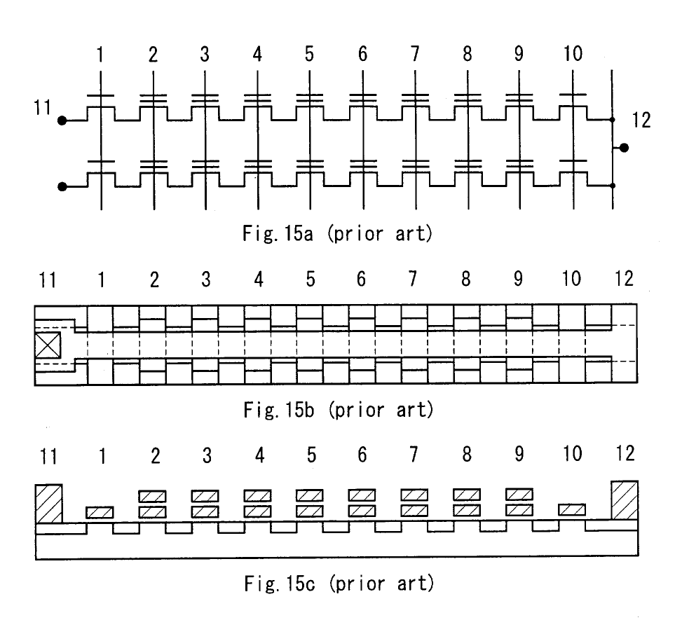

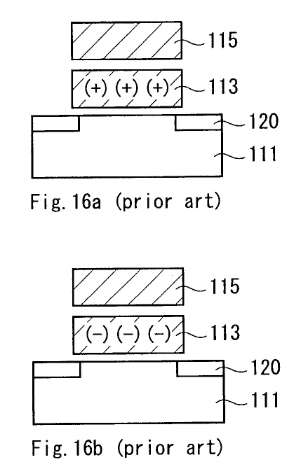

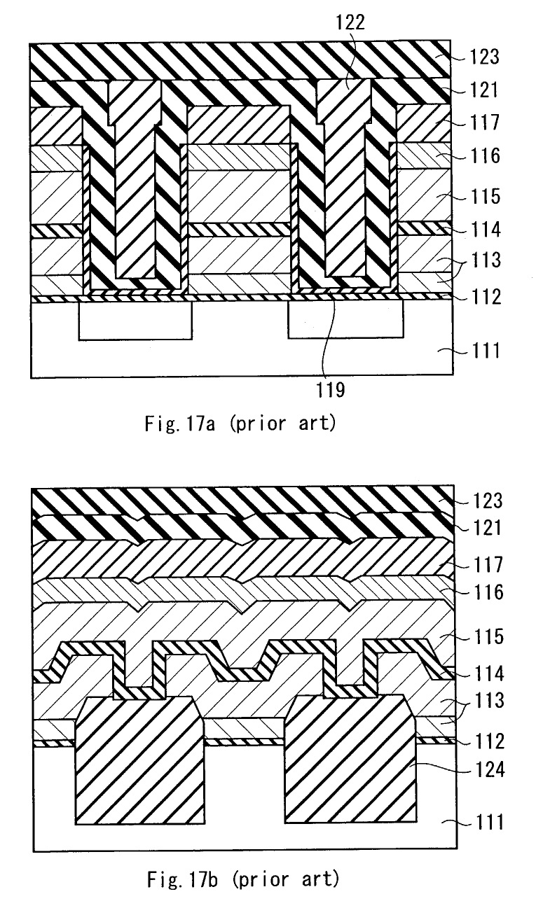

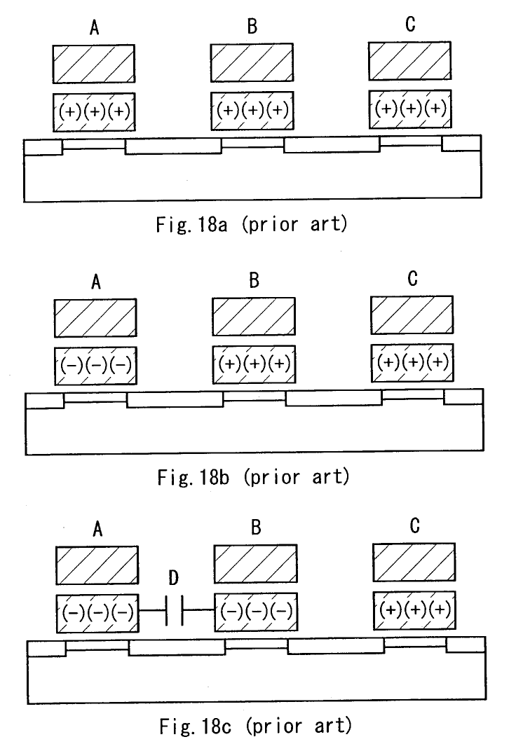

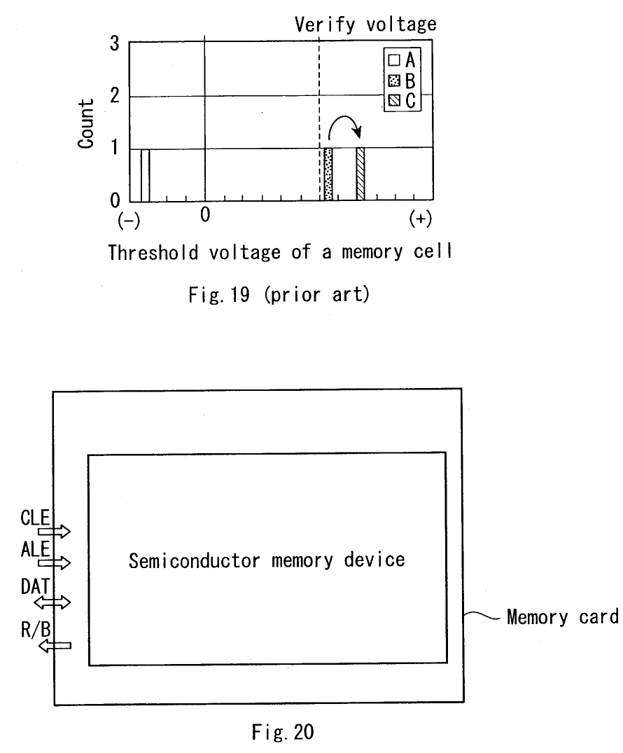

FIG. 13 shows a diagram that depicts a relationship between a thickness of a silicon nitride/a distance among gate electrodes and a fluctuation magnitude of a threshold voltage caused by an interference operation.

A conventional problem can be solved if the parasitic capacitor among the memory cells can be lowered to such an extent that it is negligible. If a static capacitor is assumed to be a parallel and a plat capacitor, the static capacitor is proportional to an area of an electrode and a dielectric constant of an insulator film, and inverse proportional to a distance among electrodes. It should be noted that a relative permittivity of a silicon nitride layer is 7.0 and a relative permittivity of a silicon oxide layer is 3.0. A thickness of the silicon nitride layer can be thin in order to low the static capacitor. However, when the thickness of the silicon nitride layer becomes thin excessively, a controllability of a process may be worse and low a yield. Therefore, we need know how about the thickness of the silicon nitride layer, and the thickness of the silicon nitride layer will be very important.

We had an experiment to explore the appropriate thickness of the silicon nitride layer 21 for the first embodiment of the present invention. We had a result shown in FIG. 13. As shown in FIG. 13, a horizontal axis indicates (a thickness of the silicon nitride layer 21 “a”/a space width among gate electrodes “x”) multiplied by 100. A vertical axis indicates an alteration magnitude of a threshold voltage (a programmed data) caused by the interference operation among the memory cells adjacent to each other. In this result, the alteration magnitude of the threshold voltage (the programmed data) can be smaller at about 15% of (a/x) multiplied by 100.

Therefore, The (a/x) multiplied by 100 can be 15% or less, thereby efficiently providing products with a stable yield and a high performance. It is noted that the thickness of the silicon nitride layer “a” for the space width of the gate electrodes adjacent to each other “x” is about 1% or more because of a process controllability.

In the first embodiment described above, the silicon nitride layer 21 “a” is formed to cover the memory cells, and the thickness of the silicon nitride layer 21 is 15% or less for the space width among the gate electrodes “x”. Thereby, even if a design rule become, for instance, 180 nm or less, the parasitic capacitor among the memory cells adjacent to each other can be reduced, and an influence of the interference operation among the memory cells adjacent to each other caused by the parasitic capacitor can be reduced. Therefore, we can provide a NAND type flash memory device that is made by an easier design and made with a high stability of operation, a high yield, and a high reliability.

A second embodiment of this present invention is an example of non-volatile memory device with LDD structure in order to control a short channel effect caused by a down-sizing of the memory cells.

FIG. 14 shows a cross sectional view of the non-volatile memory device of the second embodiment in this present invention. In shown in FIG. 14, in the second embodiment of this present invention, the second embodiment is different from the first embodiment in that a spacer insulation film 30 is formed on a side wall of the memory cell, and diffusion layers for a LDD structure are formed.

In detail, the spacer insulation film 30 is formed on a silicon oxide layer 19 that is formed on a silicon substrate 11 and a side surface of a gate electrode. First and second diffusion layers 20a and 20b are formed on the silicon substrate 11 and under the spacer insulation films 30. In a case where a silicon nitride layer is used as the spacer insulation film 30, a total thickness “b” of the spacer insulation film 30 and a silicon nitride layer 21 is 15% or less for a space width among the gate electrodes. On the other hand, in a case where an insulation layer other than a silicon nitride is used as the spacer insulation films 30 the silicon nitride layer 21 is 15% or less for the space width among the gate electrodes. It is noted that the space width among the gate electrodes is about 1% or more because of the process controllability.

The first diffusion layers 20a are formed on the semiconductor substrate 11 and under the spacer insulation film 30. The second diffusion layer 20b is formed on the semiconductor substrate 11 and under a space among the spacer insulation films facing each other (among the first diffusion layers 20a). An impurity concentration of the first diffusion layer 20b is higher than that of the second diffusion layer 20a.

The above-described semiconductor memory device of the second embodiment in the present invention is formed as follows.

In shown in FIG. 2 through FIG. 8, similarly to the first embodiment, a silicon oxide layer 19 with a thickness of, for instance, 10 nm is formed on side surfaces of a tungsten silicide layer 16, a poly crystalline silicon layer 15, an ONO layer 14, and poly crystalline silicon layers 13 and on surfaces of a silicon oxide layer 12.

As shown in FIG. 14, after P (phosphori) are injected as impurities to the semiconductor silicon substrate 11 by using an ion implantation technique, a thermal process is performed, thereby activating the impurities injected. The first diffusion layers 20a that have a low impurity concentration and an N type, are formed in the semiconductor silicon substrate 11.

As shown in FIG. 14, the spacer insulation film 30 is formed on the silicon oxide layer 19 that is formed on the side surface of the gate electrode. After P (phosphori) are injected as impurities to the semiconductor silicon substrate 11 by using an ion implantation technique, a thermal process is performed, thereby activating the impurities injected. The second diffusion layers 20b that have a high impurity concentration and an N type, are formed in the semiconductor silicon substrate 11. An explanation of following processes could be omitted because they are same as the first embodiment of the present invention.

The semiconductor memory device of the second embodiment in the present invention has same effect as that of the first embodiment. Moreover, in a case where the memory cells could be down-sized, the semiconductor memory device with a LDD structure would be prevent from having a short channel effect.

We will explain about applications having an above-mentioned semiconductor memory device. A memory card having the above mentioned semiconductor memory device is shown in FIG. 20. As shown in FIG. 20, the semiconductor memory device receives/outputs predetermined signals and data from/to an external device (not shown).

A signal line (DAT), a command line enable signal line (CLE), an address line enable signal line (ALE) and a ready/busy signal line (R/B) are connected to the memory card having the above mentioned semiconductor memory device. The signal line (DAT) transfers data, address or command signals. The command line enable signal line (CLE) transfers a signal which indicates that a command signal is transferred on the signal line (DAT). The address line enable signal line (ALE) transfers a signal which indicates that an address signal is transferred on the signal line (DAT). The ready/busy signal line (R/B) transfers a signal which indicates whether the memory device is ready or not.

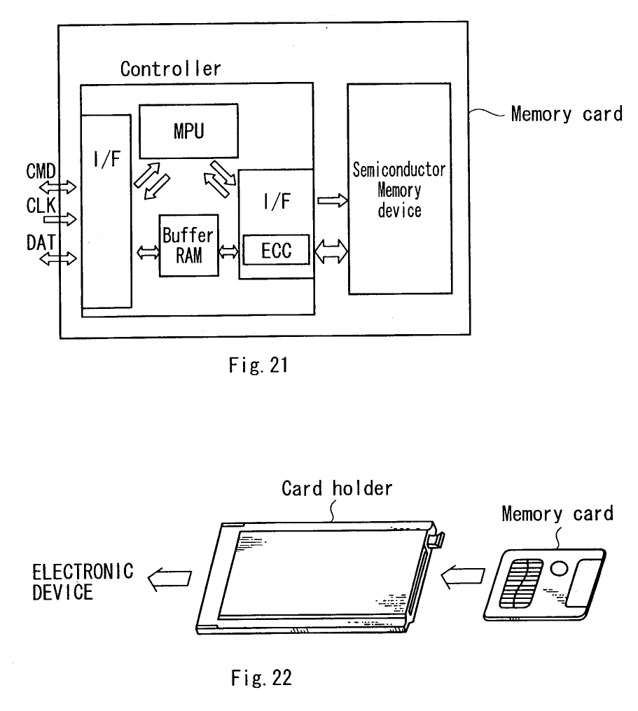

Another example of a memory card is shown in FIG. 21. The memory card shown in FIG. 21 differs from the memory card presented in FIG. 20 in that the memory card includes a controller which controls the semiconductor memory device and receives/transfers predetermined signals from/to an external device (not shown).

The controller includes an interface unit (I/F), a micro processor unit (MPU), a buffer RAM and an error correction code unit (ECC). The interface unit (I/F) receives/outputs predetermined signals from/to an external device (not shown). The micro processor unit converts a logical address into a physical address. The buffer RAM stores data temporarily. The error correction code unit generates an error correction code. And a command signal line (CMD), a clock signal line (CLK) and a signal line (DAT) are connected to the memory card.

Although we explain about the memory cards as shown above, the number of the control signal lines, bit width of the signal line (DAT) and a circuit construction of the controller could be modified suitably.

Another application is shown in FIG. 22. A memory card holder to which the memory card is inserted, is shown in FIG. 22. And the card holder is connected to electronic device (not shown). The card holder may have a part of the functions of the controller.

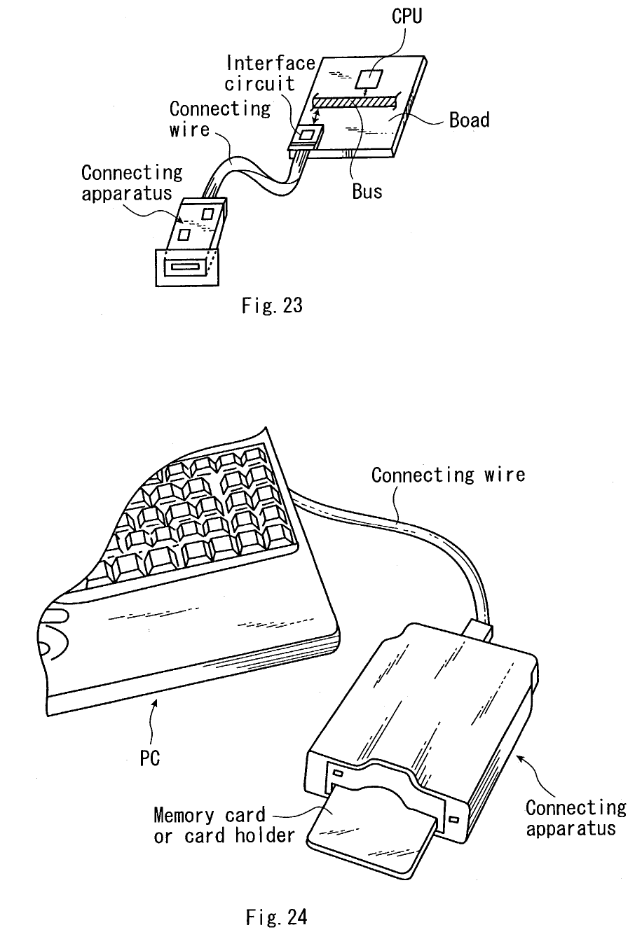

Another application is shown in FIG. 23. As shown in FIG. 23, the memory card or the card holder to which the memory card is inserted, is inserted to a connecting apparatus. The connecting apparatus is connected to a board via a connecting wire and an interface circuit. The board has a CPU (Central Processing Unit) and a bus.

Another application is shown in FIG. 24. As shown in FIG. 24, the memory card or the card holder to which the memory card is inserted, is inserted to a connecting apparatus. The connecting apparatus is connected to PC (Personal Computer) via connecting wire.

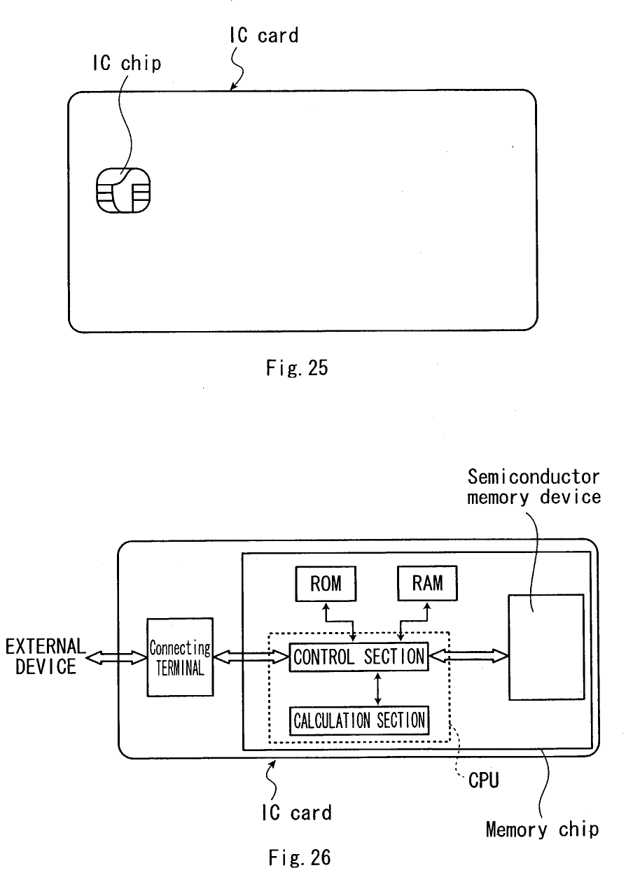

Another application is shown in FIGS. 25 and 26. As shown in FIG. 25, An IC chip that includes the above-mentioned semiconductor memory device is located on an IC card that is made of plastic or something like that. FIG. 26 shows a detail block diagram of the IC card and the IC chip presented in FIG. 25. The IC chip has a connecting terminal that is configured to connect to an external device (not shown), and a memory chip that includes the above-mentioned semiconductor memory device, a ROM, a RAM, and a CPU. The CPU contains a calculation section and a control section that is configured to connect to the semiconductor memory device.

The other various applications of the embodiments might be applied as well. For example, the other various applications described in U.S. Pat. No. 6,002,605 might be applied to this present invention. And the entire contents of the reference are incorporated by reference.

Additional advantages and modifications will readily occur to those skilled in the art. Therefore, the invention in its broader aspects is not limited to the specific details and representative embodiments shown and described herein. Accordingly, various modifications may be made without departing from the spirit or scope of the general inventive concept as defined by the appended and their equivalents.

What is claimed is:

1. A semiconductor memory device having a side wall insulation film, comprising:
a first memory cell located on an active area of a semiconductor substrate, the first memory cell having a first gate electrode, a first source electrode, and a first drain electrode;
a second memory cell located on the semiconductor substrate, the second memory cell being apart from the first memory cell in a first distance and having a second gate electrode, a second source electrode, and a second drain electrode;
a silicon nitride layer formed above the first and second memory cells to cover the first and the second memory cells, a proportion of a thickness of the silicon nitride layer formed on a side surface of one of the first and second gate electrodes to the first distance between the first and the second memory cells being more than 0% and 15% or less.

2. The semiconductor memory device having a side wall insulation film according to the claim 1, the first gate electrode of the first memory cell having a first gate insulating film formed on the active area, a first floating gate formed on the first gate insulating film, a second gate insulating film formed on the first floating gate and a first control gate formed on the second gate insulating film;
the second gate electrode of the second memory cell having a third gate insulating film formed on the active area, a second floating gate formed on the third gate insulating film, a fourth gate insulating film formed on the second floating gate and a second control gate formed on the fourth gate insulating film; and
the silicon nitride layer covered side surfaces of the first and the second control gates, the second and the fourth gate insulating films, and the first and the second floating gates.

3. The semiconductor memory device having a side wall insulation film according to the claim 1, further comprising an element isolation area adjacent to the active area of the semiconductor substrate, the element isolation area being a sallow trench isolation structure.

4. The semiconductor memory device having a side wall insulation film according to the claim 1, further comprising a silicon oxide layer formed between the silicon nitride layer and the side surface of the first and the second memory cells.

5. The semiconductor memory device having a side wall insulation film according to the claim 1, wherein the first distance is more than 0 nm and 180 nm or less.

6. The semiconductor memory device having a side wall insulation film according to the claim 1, the proportion of the thickness of the silicon nitride layer formed on the side surface of one of the first and second gate electrodes to the first distance between the first and the second memory cells being more than 1% and 15% or less.

7. The semiconductor memory device having a side wall insulation film according to the claim 1, further comprising a side wall insulating film formed between the silicon nitride layer and the side surfaces of the first and the second memory cells, the side wall insulating film being other than a silicon nitride.

8. A memory card including the semiconductor memory device recited in claim 1.

9. A card holder to which the memory card recited in claim 8 is inserted.

10. A connecting device to which the memory card recited in claim 8 is inserted.

11. The connecting device according to the claim 10, the connecting device is configured to be connected to a computer.

12. A memory card including the semiconductor memory device recited in claim 1 and a controller which controls the semiconductor memory device.

13. A card holder to which the memory card recited in claim 12 is inserted.

14. A connecting device to which the memory card recited in claim 12 is inserted.

15. The connecting device according to the claim 14, the connecting device is configured to be connected to a computer.

16. An IC card on which an IC chip that includes the semiconductor memory device recited in claim 1 is located.

17. A semiconductor memory device having a side wall insulation film, comprising:
a first memory cell located on an active area of a semiconductor substrate, the first memory cell having a first gate electrode, a first source electrode and a first drain electrode;
a second memory cell located on the semiconductor substrate, the second memory cell being apart from the first memory cell in a first distance and having a second gate electrode, a second source electrode and a second drain electrode;
first silicon nitride layers each of which formed above side surfaces of the first and second gate electrodes respectively; and
a second silicon nitride layer formed above the first silicon nitride layer to cover the first and the second memory cells, a proportion of a total thickness of the first and the second silicon nitride layers formed on a side surface of one of the first and second gate electrodes to the first distance between the first and the second memory cells being more than 0% and 15% or less.

18. The semiconductor memory device having a side wall insulation film according to the claim 17, the first gate electrode of the first memory cell having a first gate insulating film formed on the active area, a first floating gate formed on the first gate insulating film, a second gate insulating film formed on the first floating gate and a first control gate formed on the second gate insulating film;
the second gate electrode of the second memory cell having a third gate insulating film formed on the active area, a second floating gate formed on the third gate insulating film, a fourth gate insulating film formed on the second floating gate and a second control gate formed on the fourth gate insulating film; and
the silicon nitride layer covered side surfaces of the first and the second control gates, the second and the fourth gate insulating films and the first and the second floating gates.

19. The semiconductor memory device having a side wall insulation film according to the claim 17, further comprising an element isolation area adjacent to the active area of the semiconductor substrate, the element isolation area being a sallow trench isolation structure.

20. The semiconductor memory device having a side wall insulation film according to the claim 17, wherein the first distance is more than 0 nm and 180 nm or less.

21. The semiconductor memory device having a side wall insulation film according to the claim 17, the total proportion of the thickness of the first and the second silicon nitride layers formed on the side surface of one of the first and second gate electrodes to the first distance between the first and the second memory cells being more than 1% and 15% or less.

22. A memory card including the semiconductor memory device recited in claim 17.

23. A card holder to which the memory card recited in claim 22 is inserted.

24. A connecting device to which the memory card recited in claim 22 is inserted.

25. The connecting device according to the claim 24, the connecting device is configured to be connected to a computer.

26. A memory card including the semiconductor memory device recited in claim 17 and a controller which controls the semiconductor memory device.

27. A card holder to which the memory card recited in claim 26 is inserted.

28. A connecting device to which the memory card recited in claim 26 is inserted.

29. The connecting device according to the claim 28, the connecting device is configured to be connected to a computer.

30. An IC card on which an IC chip that includes the semiconductor memory device recited in claim 17 is located.
